(19) United States
(12) Patent Application Publication
(10) Pub. No.: US 2026/0323912 A1
(43) Pub. Date: Oct. 15, 2026

(54) MEMORY CELL WITH CYLINDRICAL CAPACITOR

(71) Applicant: Samsung Electronics Co., Ltd., Suwon-si (KR)

(72) Inventors: Dongwan KIM, San Jose, CA (US); Chunhui DAI, San Jose, CA (US); Don Koun LEE, San Jose, CA (US); Kwangho AHN, Santa Clara, CA (US); Sumaiya WAHID, San Jose, CA (US); Wangee KIM, Dublin, CA (US)

(21) Appl. No.: 19/415,767

(22) Filed: Dec. 10, 2025

Related U.S. Application Data
(60) Provisional application No. 63/789,089, filed on Apr. 15, 2025.

(51) Int. Cl. H10B 12/00

(52) U.S. Cl. CPC H10B 12/30; H10B 12/03; H10B 12/05

(57) ABSTRACT

A memory cell with a cylindrical capacitor. In some embodiments, a system includes: a field-effect transistor; and a capacitor, the capacitor including: a first conductive layer, forming a first electrode of the capacitor, the first conductive layer being a tube having an axis parallel to a first direction; an insulating layer, on an inner surface and an outer surface of the first conductive layer; and a second conductive layer, on an inner surface and an outer surface of the insulating layer, the second conductive layer forming a second electrode of the capacitor, the insulating layer having a maximum dimension, along a transverse direction, less than a channel width of the field-effect transistor, the transverse direction being perpendicular to an axis of the tube.

### CROSS-REFERENCE TO RELATED APPLICATION(S)

The present application claims priority to and the benefit of U.S. Provisional Application No. 63/789,089, filed Apr. 15, 2025, the entire content of which is incorporated herein by reference.

### FIELD

One or more aspects of embodiments according to the present disclosure relate to memory, and more particularly to a memory cell with a cylindrical capacitor.

### BACKGROUND

Memory cells may be constructed with transistors and capacitors. The dimensions of these components may affect the density at which memory cells may be fabricated on an integrated circuit.

It is with respect to this general technical environment that aspects of the present disclosure are related.

The above information disclosed in this Background section is only for enhancement of understanding of the background and therefore the information discussed in this Background section does not necessarily constitute prior art.

### SUMMARY

According to an embodiment of the present disclosure, there is provided a system, including: a field-effect transistor; and a capacitor, the capacitor including: a first conductive layer, forming a first electrode of the capacitor, the first conductive layer being a tube having an axis parallel to a first direction; an insulating layer, on an inner surface and an outer surface of the first conductive layer; and a second conductive layer, on an inner surface and an outer surface of the insulating layer, the second conductive layer forming a second electrode of the capacitor, the insulating layer having a maximum dimension, along a transverse direction, less than a channel width of the field-effect transistor, the transverse direction being perpendicular to an axis of the tube.

In some embodiments the system includes a first memory cell including the field-effect transistor and the capacitor.

In some embodiments the system includes an integrated circuit including the first memory cell and a second memory cell, in a first planar tier of the integrated circuit.

In some embodiments: a center-to-center separation between the second memory cell and the first memory cell, along a second direction, is less than 130 nm; and the second direction is parallel to the first planar tier and perpendicular to the axis of the tube.

In some embodiments, a capacitance of the capacitor is greater than 4 femtofarads.

In some embodiments, the capacitor has a maximum dimension less than 90 nm along the transverse direction.

In some embodiments, the capacitor has a maximum dimension less than 90 nm along the transverse direction.

In some embodiments: the integrated circuit includes four planar tiers including the first planar tier, and a mean pitch of the four planar tiers is less than 90 nm.

In some embodiments, a capacitance of the capacitor is greater than 4 femtofarads.

According to an embodiment of the present disclosure, there is provided a system, including: a field-effect transistor having a channel; a capacitor; and a contact connecting the channel to a first electrode of the capacitor, the capacitor including: a first conductive layer, forming the first electrode of the capacitor, the first conductive layer being a tube having an axis parallel to a first direction; an insulating layer, on an inner surface and an outer surface of the first conductive layer; and a second conductive layer, on an inner surface and an outer surface of the insulating layer, the second conductive layer forming a second electrode of the capacitor, a first end of the contact being wider than a second end of the contact, the first end of the contact being nearest the field-effect transistor, and the second end of the contact being nearest the capacitor.

In some embodiments the system includes a first memory cell including the field-effect transistor and the capacitor.

In some embodiments the system includes an integrated circuit including the first memory cell and a second memory cell, in a first planar tier of the integrated circuit.

In some embodiments: a center-to-center separation between the second memory cell and the first memory cell, along a second direction, is less than 130 nm; and the second direction is parallel to the first planar tier and perpendicular to the axis of the tube.

In some embodiments, a capacitance of the capacitor is greater than 4 femtofarads.

In some embodiments, the capacitor has a maximum dimension less than 90 nm along a transverse direction, the transverse direction being perpendicular to an axis of the tube.

In some embodiments, the capacitor has a maximum dimension less than 90 nm along a transverse direction, the transverse direction being perpendicular to an axis of the tube.

In some embodiments: the integrated circuit includes four planar tiers including the first planar tier, and a mean pitch of the four planar tiers is less than 90 nm.

In some embodiments, a capacitance of the capacitor is greater than 4 femtofarads.

According to an embodiment of the present disclosure, there is provided an integrated circuit, including: a first planar tier including: a first memory cell; and a second memory cell, the first memory cell including: a field-effect transistor, and a capacitor, the capacitor including: a first conductive layer, forming a first electrode of the capacitor, the first conductive layer being a tube having an axis parallel to a first direction; an insulating layer, on an inner surface and an outer surface of the first conductive layer; and a second conductive layer, on an inner surface and an outer surface of the insulating layer, the second conductive layer forming a second electrode of the capacitor, the first conductive layer having a maximum dimension, along a transverse direction, less than a channel width of the field-effect transistor, the transverse direction being perpendicular to an axis of the tube.

In some embodiments, a center-to-center separation between the second memory cell and the first memory cell, along a second direction, is less than 130 nm, the second direction being parallel to the first planar tier and perpendicular to an axis of the tube.

### BRIEF DESCRIPTION OF THE DRAWINGS

These and other features and advantages of the present disclosure will be appreciated and understood with reference to the specification, claims, and appended drawings wherein:

FIG. 1A is a system-level block diagram of a computing system, according to an embodiment of the present disclosure;

FIG. 1B is a side view of a computing system, according to an embodiment of the present disclosure;

FIG. 1C is a schematic diagram of a portion of a dynamic random-access memory cell array, according to an embodiment of the present disclosure;

FIG. 2A is a perspective cutaway view of a portion of an integrated circuit, according to an embodiment of the present disclosure;

FIG. 2B is a cutaway plan view of a portion of an integrated circuit, according to an embodiment of the present disclosure;

FIG. 2C is a cutaway side view of a portion of an integrated circuit, according to an embodiment of the present disclosure;

FIG. 2D is a cutaway plan view of a portion of an integrated circuit, according to an embodiment of the present disclosure;

FIG. 2E is a graph of margin as a function of a number of tiers, according to an embodiment of the present disclosure;

FIG. 2F is a cutaway plan view of a portion of an intermediate product in the fabrication of an integrated circuit, according to an embodiment of the present disclosure;

FIG. 2G is a cutaway plan view of a portion of an integrated circuit, according to an embodiment of the present disclosure;

FIG. 3A is a cutaway perspective view of a portion of an intermediate product in the fabrication of an integrated circuit, according to an embodiment of the present disclosure;

FIG. 3B is a cutaway plan view of a portion of an intermediate product in the fabrication of an integrated circuit, according to an embodiment of the present disclosure;

FIG. 3C is a cutaway perspective view of a portion of an intermediate product in the fabrication of an integrated circuit, according to an embodiment of the present disclosure;

FIG. 3D is a cutaway plan view of a portion of an intermediate product in the fabrication of an integrated circuit, according to an embodiment of the present disclosure;

FIG. 3E is a cutaway perspective view of a portion of an intermediate product in the fabrication of an integrated circuit, according to an embodiment of the present disclosure; and

FIG. 3F is a flow chart, according to an embodiment of the present disclosure.

### DETAILED DESCRIPTION

The detailed description set forth below in connection with the appended drawings is intended as a description of exemplary embodiments of a memory cell with a cylindrical capacitor provided in accordance with the present disclosure and is not intended to represent the only forms in which the present disclosure may be constructed or utilized. The description sets forth the features of the present disclosure in connection with the illustrated embodiments. It is to be understood, however, that the same or equivalent functions and structures may be accomplished by different embodiments that are also intended to be encompassed within the scope of the disclosure. As denoted elsewhere herein, like element numbers are intended to indicate like elements or features.

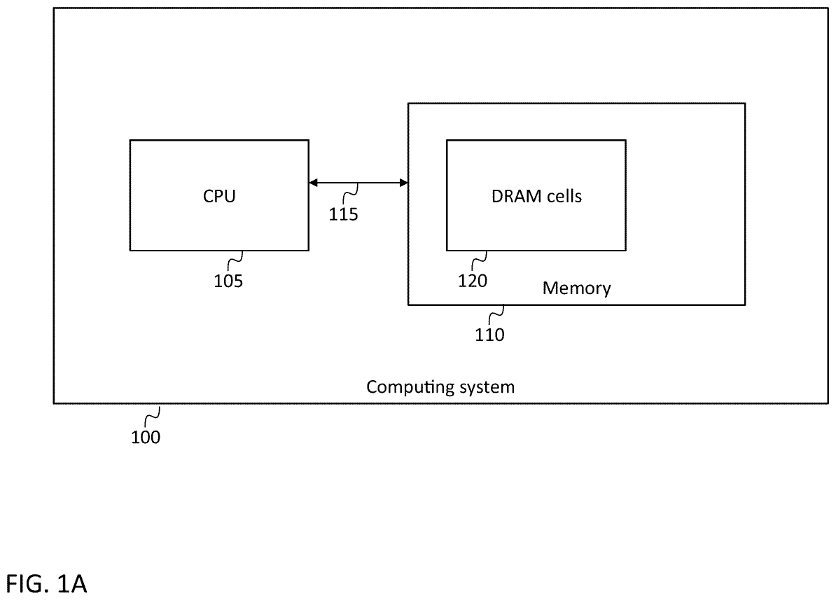

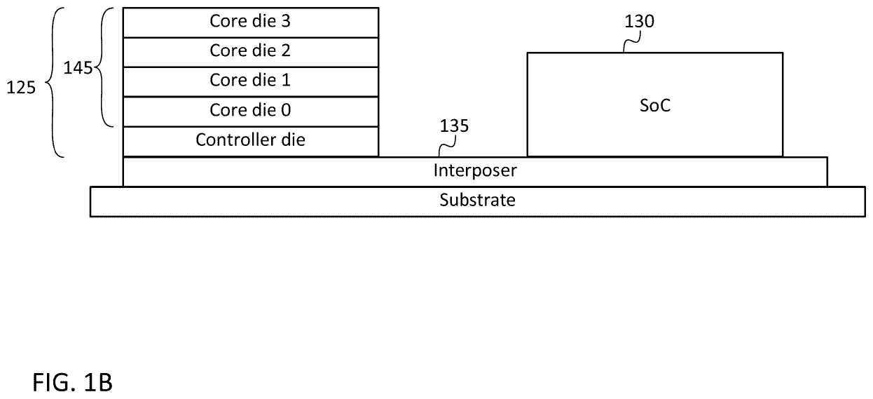

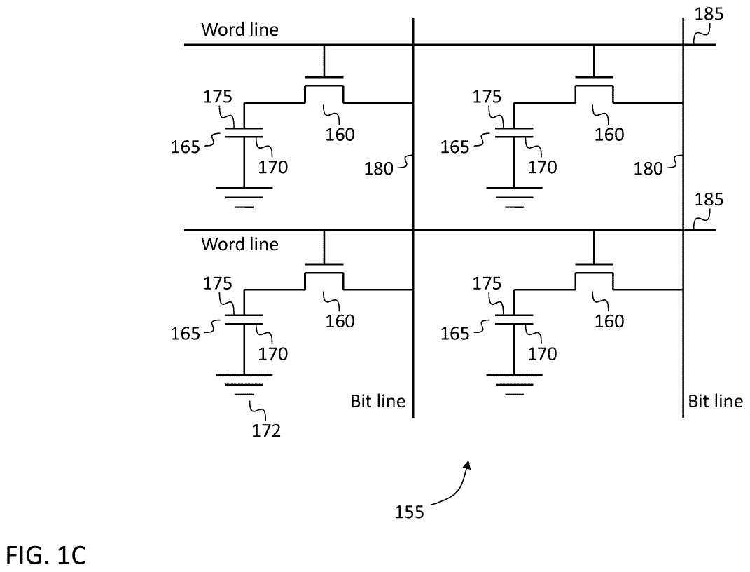

FIG. 1A depicts a simplified diagram of a computing system 100, in some embodiments. A central processing unit (CPU) 105 is connected to a memory 110, e.g., through a serial connection 115. The memory 110 may include (i) a dynamic random-access memory cell array 120 including a plurality of dynamic random-access memory cells and (ii) input-output circuits.

FIG. 1B depicts a computing system including a stacked memory device 125 (which may be a high bandwidth memory (HBM)), and a system on a chip (SoC) 130 connected to the stacked memory device 125. The system on a chip 130 may include various processing circuits such as a central processing unit (CPU) or a graphics processing unit (GPU). Serial data links, which may include conductors extending, on the top surface of an interposer 135, from the memory device 125 to the system on a chip 130, may be used for data transfers and other communications between the stacked memory device 125 and the system on a chip 130. The memory device 125 and the system on a chip 130 may also be secured to the interposer 135. The interposer 135 may be secured to a substrate 140, which may be an organic substrate (e.g., a printed circuit board composed of one or more layers of fiberglass reinforced plastic, with copper conductors on the one or more layers of fiberglass reinforced plastic, and with copper vias providing conductive paths through the one or more layers of fiberglass reinforced plastic). The substrate 140 may have conductors on its lower surface, for mounting the substrate on, and forming connections with, a larger printed circuit board (e.g., a system board) that may also be composed of one or more layers of fiberglass reinforced plastic. Such conductors may be a ball grid array, for example, which may include a grid of solder balls for soldering the lower surface of the substrate 140 to a top surface of a larger printed circuit board.

The stacked memory device 125 may include a plurality of stacked core dies 145 and a controller die 150 (which may also be referred to as a base die). Through silicon vias may form connections between (i) each core die 145 of the plurality of stacked core dies 145 and (ii) the controller die 150. The controller die 150 may manage the data transfers between the system on a chip 130 and the plurality of stacked core dies 145.

Each core die 145 of the plurality of stacked core dies 145 may include memory, such as dynamic random-access memory (DRAM) (e.g., synchronous dynamic random-access memory (SDRAM)).

FIG. 1C shows a portion of a dynamic random-access memory cell array 120, the portion including four dynamic random-access memory cells 155. The dynamic random-access memory cell array 120 may include more than four dynamic random-access memory cells 155; only four dynamic random-access memory cells 155 are shown in FIG. 1C for ease of illustration. Each of the dynamic random-access memory cells 155 includes a transistor 160 and a capacitor 165. The capacitor includes two electrodes, a top electrode 170 which is connected to ground connection 172, and a bottom electrode 175 which is connected to a first source-drain (e.g., a first end of the channel) of the transistor 160. The other source-drain of the transistor 160 is connected to a respective shared bit line 180. The gate of each transistor 160 is connected to a respective word line 185.

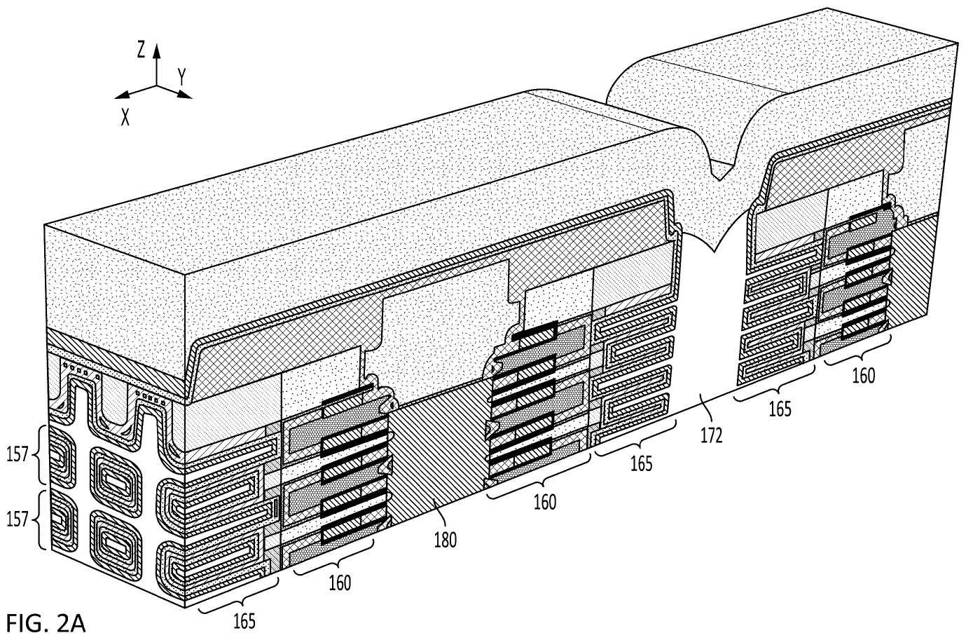

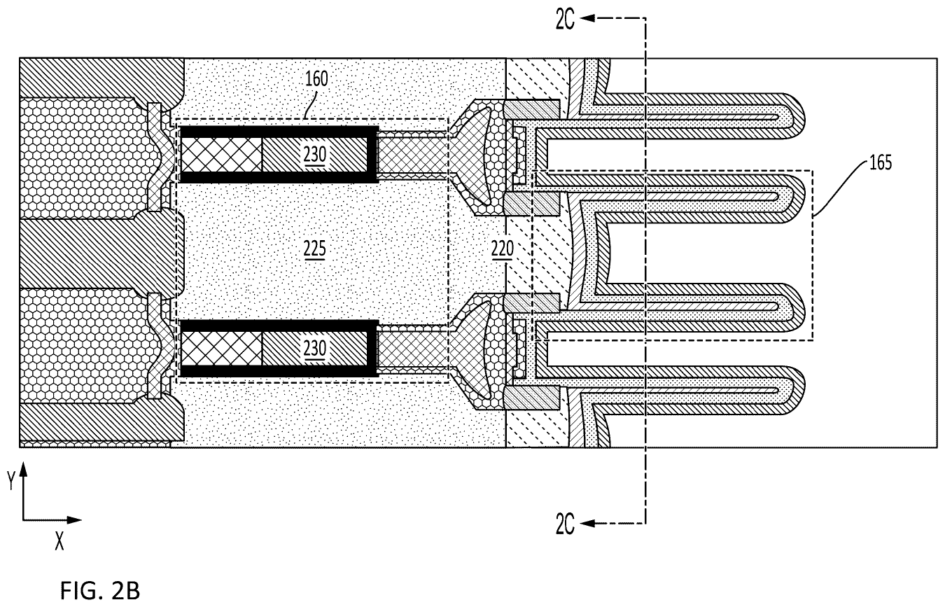

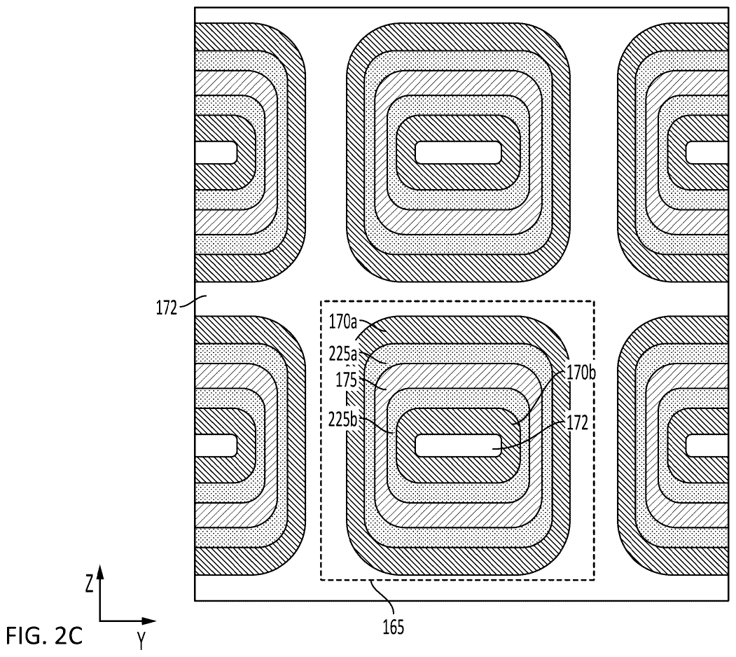

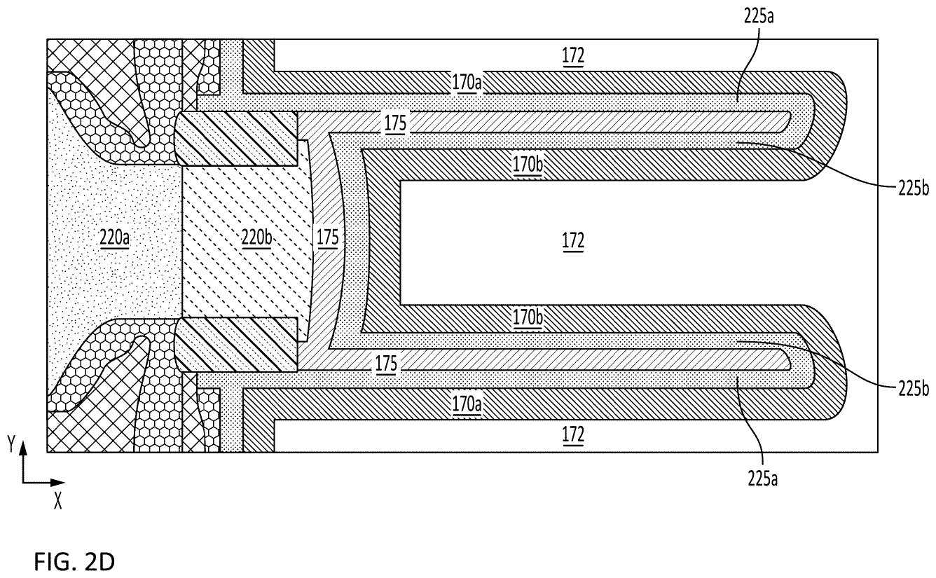

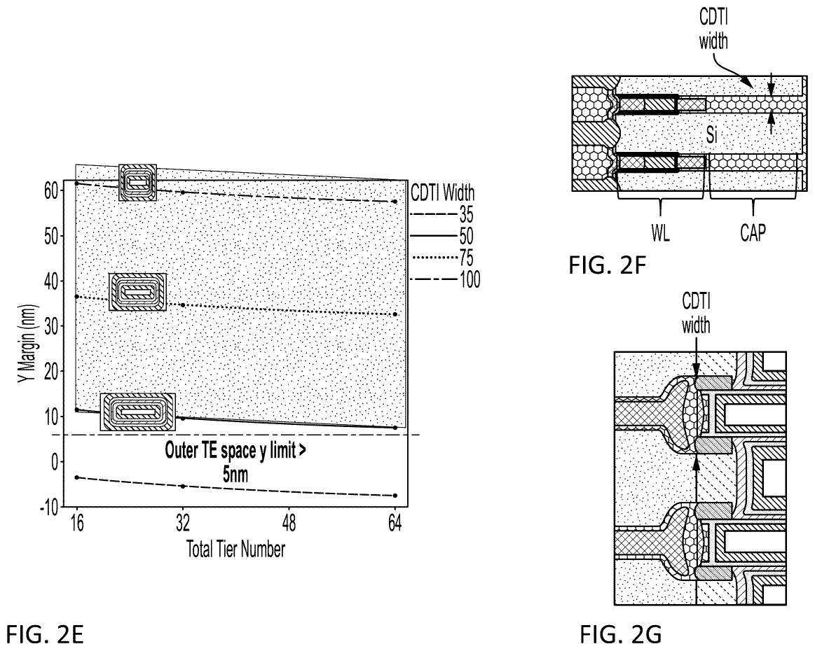

The dynamic random-access memory cells 155 may be fabricated on a integrated circuit, e.g., on a silicon complementary metal-oxide semiconductor (CMOS) integrated circuit. FIG. 2A shows a cutaway view of portion of such a complementary metal-oxide semiconductor integrated circuit.

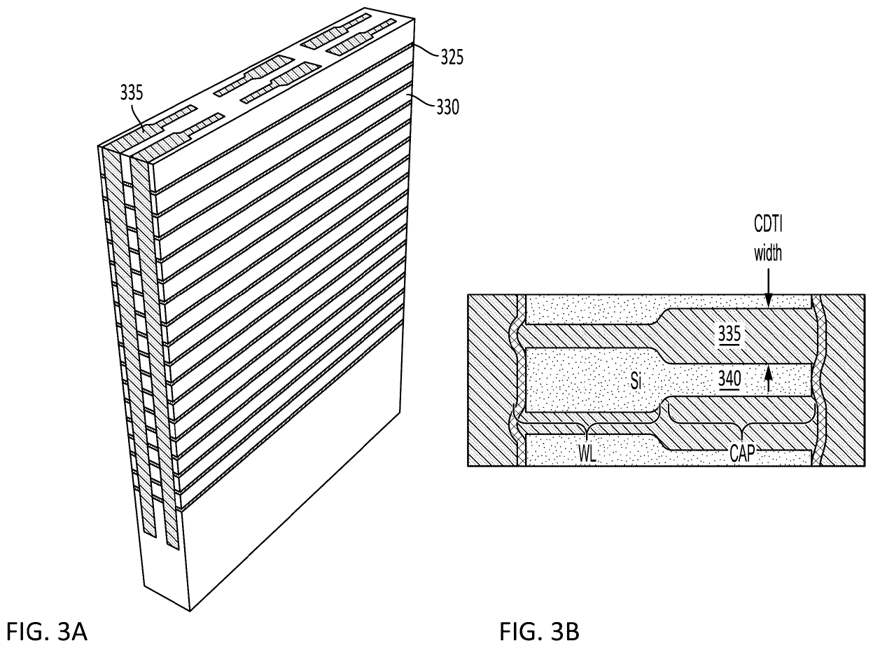

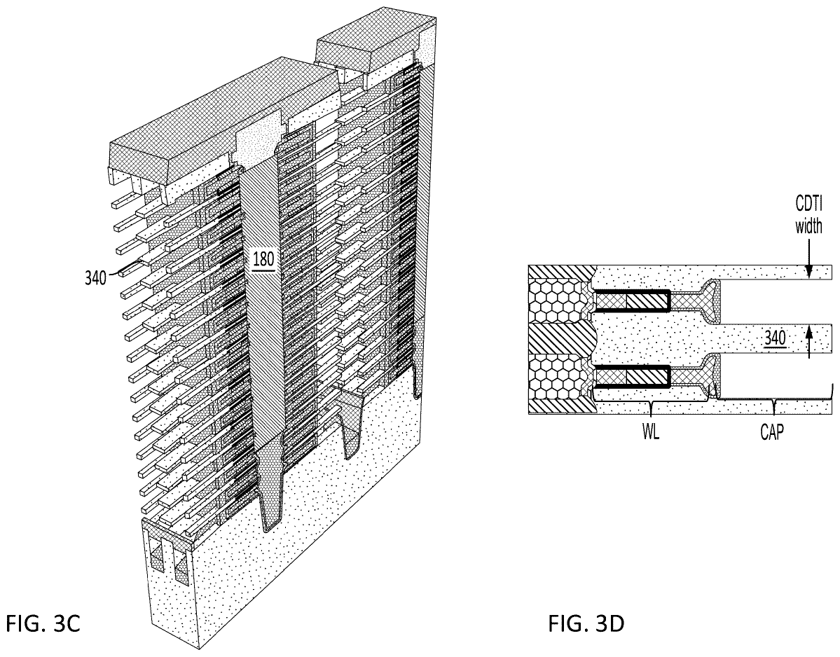

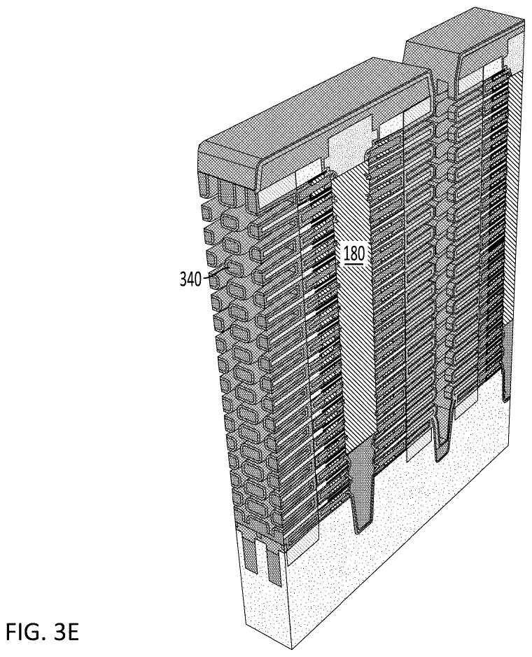

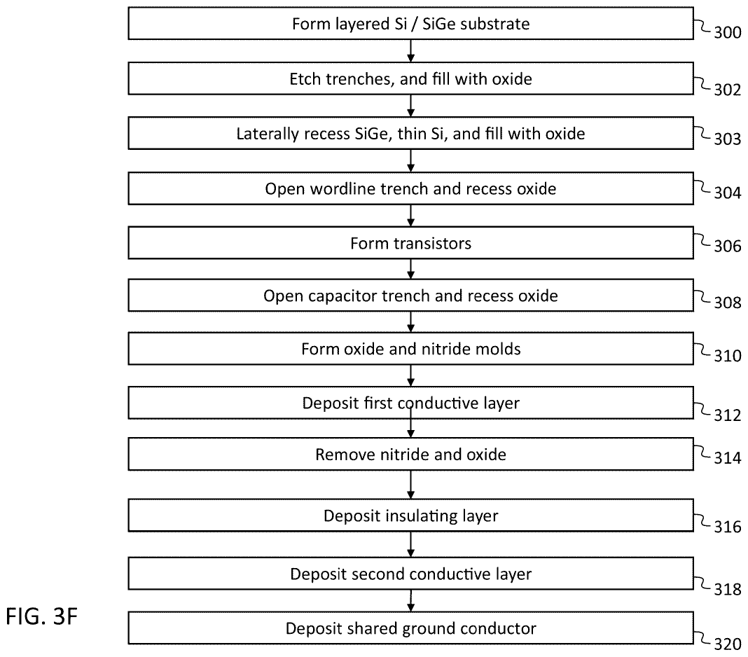

Each of FIG. 2A-2D and 2G-3E is drawn to scale for one embodiment. FIG. 2A shows three axes, an X axis, a Y axis, and a Z axis, that may be used to refer to three corresponding orthogonal directions in the perspective drawing of FIG. 2A. The integrated circuit includes a plurality of planar tiers 157 each parallel to the substrate, and each including a plurality of transistors 160 and capacitors 165, as shown, and as discussed in further detail below. FIG. 2A shows a portion of an integrated including only two such tiers, for ease of illustration. In some embodiments, an integrated circuit may have more than two tiers, e.g., it may include between 3 and 64 tiers.

The transistors 160 are arranged in columns, each column being aligned along the Z axis, and in Y-rows, each Y-row extending along the Y direction. Vertical conductors (parallel to the Z direction) that form shared bit lines 180 alternate with vertical conductors (parallel to the Z direction) that form shared ground connections 172. Between each shared bit line 180 and the adjacent shared ground connection 172 is a column of transistors 160 and a column of capacitors 165, each transistor 160 of the column of transistors 160 being connected to a respective transistor-capacitor contact 220 (FIG. 2B) which in turn is connected to a bottom electrode 175 of a respective capacitor 165. Each combination of a transistor 160, a transistor-capacitor contact 220, and a capacitor 165 is oriented, between the shared bit line 180 to which it is connected and the shared ground connection 172 to which it is connected, such that the capacitor 165 is nearest to, and connected to, the shared ground connection 172, and the transistor 160 is nearest to, and connected to, the shared bit line 180. The set of combinations (each combination including a transistor 160, a transistor-capacitor contact 220, and a capacitor 165) are arranged (with alternating orientations, as mentioned above) along the X direction in rows that may be referred to as X-rows. Shared word lines 185 connect the gates of the transistors 160 of each Y-row together.

FIG. 2B is an enlarged plan-view cross section of a combination including a transistor 160, a transistor-capacitor contact 220, and a capacitor 165. The X axis and the Y axis are also shown in FIG. 2B. The transistor 160 includes a channel 225 and a gate 230, which may extend around the channel 225 (e.g., the transistor 160 may be a gate-all-around transistor). The transistor-capacitor contact 220 may have a wide end (at left, in FIG. 2B) connected to the channel 225 of the transistor 160, and a narrow end (at right, in FIG. 2B) connected to the bottom electrode 175 of the capacitor 165. As used herein, a “plan view” means a view taken along the Z axis.

FIG. 2C is a side cross-sectional view. The view of FIG. 2C is taken along the X axis, e.g., the cutting plane used to generate the cross-sectional view of FIG. 2C is parallel to the Y-Z plane. The cross-section is taken at a cutting plane extending through a set of capacitors 165, e.g., it may be taken along the cutting plane 2C-2C shown in FIG. 2B, which is parallel to the Y-Z plane.

As may be seen from FIG. 2C, each capacitor 165 may include (e.g., consist of) a plurality of concentric layers, each layer having the shape of a rounded rectangle (e.g., a rounded square). The layers may include a first conductive layer 175, which may form the bottom electrode 175 of the capacitor 165. The layers may further include an insulating layer 225, which includes a first portion 225a on the outer surface of the first conductive layer 175 and a second portion 225b on the inner surface of the first conductive layer 175. The layers may further include a second conductive layer 170, which forms the top electrode 170, and which includes a first portion 170a on the outer surface of the first portion 225a of the insulating layer 225 and a second portion 170b on the inner surface of the second portion 225b of the insulating layer 225.

Each layer of the capacitor may be a tube (e.g., a tube with a cross section that is a rounded rectangle). The ends of each tube may be referred to as the proximal end and the distal end, with (i) the proximal end being the end nearest to (and, in the case of the first conductive layer 175—which may form the bottom electrode 175 of the capacitor 165 connected, by the transistor-capacitor contact 220 to) the transistor 160, and with (ii) the distal end being the end that is most distant from the transistor 160. For example, the first conductive layer 175 may be a tube that is closed at the proximal end as shown.

The insulating layer 225 may be single layer in the sense that (i) the first portion 225a of the insulating layer 225 and the second portion 225b of the insulating layer 225 may be joined at the distal end of the first conductive layer 175, as shown in the cross-sectional views of FIGS. 2B and 2D. This joining of the first portion 225a of the insulating layer 225 and the second portion 225b of the insulating layer 225 may be the result of the method used to form the insulating layer 225. For example, the insulating layer 225 may be formed in a single deposition process, with the first portion 225a of the insulating layer 225 and the second portion 225b of the insulating layer 225 being formed concurrently, as a single insulating layer 225 that covers the inner surface of the first conductive layer 175 and wraps around to also cover the outer surface of the first conductive layer 175.

FIG. 2D is a further enlarged plan view of a cross section of a portion of the combination (including a transistor 160, a transistor-capacitor contact 220, and a capacitor 165) illustrated in FIG. 2B. The portion illustrated in FIG. 2D includes the transistor-capacitor contact 220 (which includes a first portion 220a and a second portion 220b). A capacitor with the structure illustrated in FIGS. 2C and 2D may be referred to as a “cylindrical” capacitor.

The portion illustrated in FIG. 2C further includes a capacitor 165. The transistor-capacitor contact 220 may include a first portion 220a and a second portion 220b. The first portion 220a of the transistor-capacitor contact 220 may be composed of undoped silicon or of silicon with the same doping (if any) as the channel 225 of the transistor 160. The second portion 220b of the transistor-capacitor contact 220 may be composed of highly doped silicon, e.g., to eliminate or reduce the magnitude of a Schottky barrier which might otherwise form at the interface between the transistor-capacitor contact 220 and the bottom electrode 175.

The ends of the transistor-capacitor contact 220 may be referred to as the proximal end and the distal end, with the proximal end being the end nearest to (and connected to) the transistor 160 and with the distal end being the end that is most distant from the transistor 160 (and connected to the bottom electrode 175).

As shown in FIGS. 2B and 2D, and as mentioned above, the distal end of the transistor-capacitor contact 220 may be narrower than the proximal end of the transistor-capacitor contact 220. For example, the first portion 220a of the transistor-capacitor contact 220 may be tapered. The first portion 220a of the transistor-capacitor contact 220 may have a width equal to the width of the channel 225 of the transistor 160 at the proximal end (the end closest to the channel 225 of the transistor 160) of the first portion 220a of the transistor-capacitor contact 220. The transistor-capacitor contact 220 may have a smaller width (e.g., a width that is between 10% smaller and 70% smaller than the width of the channel 225 of the transistor 160) at the distal end of the transistor-capacitor contact 220.

In some embodiments, the reduction in width along the length of the transistor-capacitor contact 220 may be more abrupt or more gradual than that illustrated in FIGS. 2B and 2D. For example, the taper may extend along the entire length of the transistor-capacitor contact 220 (so that the entire transistor-capacitor contact 220 is tapered), or the tapered portion may be located elsewhere along the length of the transistor-capacitor contact 220.

Because a silicon beam (or “pillar”) having the same width as the width of the transistor-capacitor contact 220 at the distal end of the transistor-capacitor contact 220 may serve as a template for the formation of the capacitor 165, the narrower width of the distal end of the transistor-capacitor contact 220 may result, for reasons discussed below, in a capacitor having a smaller maximum transverse dimension (e.g., a smaller maximum dimension along the Y direction). This in turn may make it possible to fabricate the capacitors (and the dynamic random-access memory cells 155) on a smaller (e.g., finer) pitch than would be achievable if the silicon beam had a uniform width (in the Y direction) equal to the width of the channel 225 of the transistor 160.

FIG. 2E is a graph of Y margin as a function of the number of tiers (or “planar tiers”) of an integrated circuit, and as a function of the cell deep trench isolation (CDTI) width.

For purposes of FIG. 2E, the CDTI width is the width of a portion of a trench formed to define a beam or “pillar”, which in subsequent processing is used to form (i) the channel of a transistor 160 and (ii) a template for the forming of a capacitor 165. As shown in FIG. 2F, the CDTI width is the width of the trench at a point along the beam that is within the portion of the beam that will become a template for the forming of a capacitor 165. As such, the greater the CDTI width, the narrower the beam will be at this point, and the smaller the transverse dimension (in the Y direction) of the capacitor.

FIG. 2F shows an embodiment in which the CDTI width is the same as the width of the trench at the portion of the beam that will become the channel of the transistor 160, e.g., the CDTI width is 35 nm, corresponding to a beam width of 80 nm (for a pitch of 115 nm in the Y direction, for the capacitors and transistors). FIG. 2E shows that for this CDTI width, the Y margin (which is one-half of the amount of space available, between adjacent capacitors, before the formation of the second conductive layer 170) is less than the minimum required (5 nm, shown by the dash-dotted horizontal line). As such, a CDTI width of 35 nm is not sufficient to form capacitors with the structure illustrated in FIGS. 2C and 2D.

A greater CDTI width, such as that illustrated in FIG. 2G (which has a CDTI width of approximately 75 nm) may however be sufficient, as illustrated by the graph of FIG. 2E, which shows that a CDTI width of 50 nm or greater results in sufficient Y margin, for 64 or fewer tiers.

FIG. 3A-3F shows intermediate products and a method of fabricating a dynamic random-access memory cell array on an integrated circuit, in some embodiments. Although FIG. 3F illustrates various operations in such a method, embodiments according to the present disclosure are not limited thereto. For example, according to some embodiments, such a method may include additional operations or fewer operations, or the order of operations may vary (unless otherwise explicitly stated or implied) without departing from the spirit and scope of embodiments according to the present disclosure.

FIG. 3A shows an early intermediate product, which may be formed at 300 and 302 (FIG. 3F). The intermediate product of FIG. 3A includes alternating layers of silicon (Si) 325 and silicon germanium (SiGe) 330, and a plurality of trenches 335, which are formed as part of a process that may be referred to as cell deep trench isolation (CDTI). The etching of the trenches may be performed by a dry etch process, and the oxide (e.g., silicon dioxide) may be deposited using chemical vapor deposition.

FIG. 3B is a top view of the intermediate product, showing (i) the portion of the remaining silicon (after the forming of the trenches 335) that will become the channel of the transistor and which is where the word lines (WL) will be formed, and (ii) the portion 340 (labeled “CAP”) which, in a later processing step, acts as a template for the formation of (and affects the width of) the capacitor 165. The CDTI width, which affects the width of the capacitor 165, is shown by arrows on the latter portion.

FIG. 3C shows an intermediate product formed by operations 303, 304 and 306 of FIG. 3F. At 303, the layers of silicon germanium (SiGe) 330 may be recessed, each layer of silicon 325 may be thinned (in the Z direction) to a thickness of e.g., 15 nm, and be filled a portion of the empty volume formed by the recessing may be filled with oxide. Next, at 304, the word line trench may be opened and the oxide may be partially etched away laterally for transistor formation. At 306, transistors may be formed as follows. Gate oxide may be formed for each transistor, nitride spacers may be formed, and oxide (inter-tier oxide) may be formed between the nitride spacers. The nitride may be partially recessed, the gate formed, and slightly recessed, and another nitride spacer may be formed. The shared bit line 180 may then be formed. After forming the word line, the capacitor trench may be opened and the oxide may be laterally recessed, leaving the beams (or “pillars”) 340 exposed. FIG. 3D shows a plan view of a portion of the intermediate product of FIG. 3C, showing a beam 340 and the CDTI width.

FIG. 3E shows an intermediate product that may be formed by operation 308 of FIG. 3F. To form the intermediate product of FIG. 3E, a layer of oxide (e.g. a layer having a thickness of 15 nm) may be deposited on each of the beams 340, and a layer of nitride (e.g. silicon nitride) may then be formed on the layer of oxide. This may form an array of coated beams 345, as illustrated.

Operations 310-320 may then be used to form the final product (shown, e.g., in FIG. 2A). At 310, nitride molds (for forming the capacitors 165) may be formed as follows. The space between the oxide and nitride coated beams 340 may be filled with oxide, and the oxide may be recessed slightly so that the tip of each oxide and nitride coated beam 340 extends slightly out of the oxide. An additional nitride liner may be added over the oxide, so that the exposed surface is a layer of nitride, with a bump at the location of the end of each of the beams 340. The tip of each bump may be etched, exposing the oxide below the nitride. The oxide coating on each the beams 340, and the beams 340 themselves may then be removed (to the distal end of the transistor-capacitor contact 220), to form the mold.

Each mold may be a channel in the nitride, on the inner surface of which the first conductive layer 175 may be formed in the shape of a tube, at 312 (FIG. 3F). The oxide and nitride may be removed, at 314 (FIG. 3F) from around the first conductive layer 175, which may be tubular, of each of the capacitors 165. The insulating layer 225 may then be deposited, at 316 (on the inner and outer surfaces of the first conductive layer 175 of each of the capacitors 165), and the second conductive layer 170 may be deposited, at 318 (on the inner and outer surfaces of the insulating layer 225 of each of the capacitors 165). Finally, the shared ground connection 172 may be deposited, at 320.

Various deposition methods may be used in the operations of FIG. 3F, including chemical vapor deposition and atomic layer deposition. Wet or dry etches may be used to remove material. Dry etches may be used when directional etching is advantageous, e.g., for forming the relatively high aspect-ratio trenches 335 of FIG. 3A.

The first conductive layer 175 (which, as mentioned above, may form the bottom electrode 175 of the capacitor 165) and the second conductive layer 170 (which, as mentioned above, may form the top electrode 170 of the capacitor 165) may be composed of titanium nitride, and the insulating layer 225 may be composed of zirconium oxide, or of any other suitable dielectric having a sufficiently high dielectric constant (e.g., a dielectric constant that is significantly higher than that of silicon dioxide (or “oxide”)).

According to an embodiment of the present disclosure, there is provided a system, including: a field-effect transistor; and a capacitor, the capacitor including: a first conductive layer, forming a first electrode of the capacitor, the first conductive layer being a tube having an axis parallel to a first direction; an insulating layer, on an inner surface and an outer surface of the first conductive layer; and a second conductive layer, on an inner surface and an outer surface of the insulating layer, the second conductive layer forming a second electrode of the capacitor. For example, as illustrated in FIG. 2B, an integrated circuit may include a combination including a transistor 160, a transistor-capacitor contact 220, and a capacitor 165, and the capacitor 165 may include, as illustrated in FIGS. 2C and 2D, a first conductive layer 175, an insulating layer 225 (including a first portion 225a and a second portion 225b) and a second conductive layer 170 (including a first portion 170a and a second portion 170b). The insulating layer may have a maximum dimension, along a transverse direction, less than a channel width of the field-effect transistor, the transverse direction being perpendicular to an axis of the tube. For example, as may be seen from FIGS. 2C and 2D (which, as mentioned above, are drawn to scale), in some embodiments the dimension of the insulating layer 225 in the Y direction may be less than the width of the channel 225 of the transistor 160.

In some embodiments the system includes a first memory cell including the field-effect transistor and the capacitor. In some embodiments the system includes an integrated circuit including the first memory cell and a second memory cell, in a first planar tier of the integrated circuit. In some embodiments: a center-to-center separation between the second memory cell and the first memory cell, along a second direction, is less than 130 nm; and the second direction is parallel to the first planar tier and perpendicular to the axis of the tube. In some embodiments: the integrated circuit includes four planar tiers including the first planar tier, and a mean pitch of the four planar tiers is less than 90 nm. For example, the integrated circuit of FIG. 2A shows two planar tiers 157. In some embodiments, the pitch (in the Z direction) of these tiers (and of additional tiers, not illustrated in FIG. 2A) may be less than 90 nm, e.g., between 50 nm and 90 nm, e.g., 80 nm. In some embodiments, the pitch, in the Y direction of the transistors 160 in a Y-row (and of the capacitors 165 connected to the transistors 160) may be less than 130 nm (e.g., the pitch may be between 70 nm and 130 nm, e.g., the pitch may be 115 nm).

In some embodiments, a capacitance of the capacitor is greater than 4 femtofarads. For example, the capacitor structure illustrated in FIGS. 2C and 2D may have a greater capacitance than a similarly-sized structure having a second conductive layer with only one portion (e.g., a second conductive layer that is only inside or outside of the first conductive layer). For example, the capacitance of such a capacitor 165 may be greater than 3.5 femtofarads, e.g., it may be between 3.5 femtofarads and 10 femtofarads, e.g., it may be 5 femtofarads. In some embodiments, the capacitor has a maximum dimension less than 90 nm along the transverse direction. For example, as may be seen from FIGS. 2C and 2D (which, as mentioned above, are drawn to scale), in some embodiments the maximum dimension of the second conductive layer 170 along the transverse direction is equal to the maximum dimension of the capacitor 165 along the transverse direction. This maximum dimension of the second conductive layer 170 along the Y direction may be less than 115 nm, e.g., it may be between 60 nm and 115 nm, or less than 90 nm, e.g., it may be 80 nm.

According to an embodiment of the present disclosure, there is provided a system, including: a field-effect transistor having a channel; a capacitor; and a contact connecting the channel to a first electrode of the capacitor, the capacitor including: a first conductive layer, forming the first electrode of the capacitor, the first conductive layer being a tube having an axis parallel to a first direction; an insulating layer, on an inner surface and an outer surface of the first conductive layer; and a second conductive layer, on an inner surface and an outer surface of the insulating layer, the second conductive layer forming a second electrode of the capacitor. In some embodiments, a first end of the contact is wider than a second end of the contact, the first end of the contact being nearest the field-effect transistor, and the second end of the contact being nearest the capacitor. This is illustrated, for example, in FIG. 2D in which the transistor-capacitor contact 220 includes a first portion 220a and a second portion 220b, and in which the proximal end of the transistor-capacitor contact 220 is wider than the distal end of the transistor-capacitor contact 220.

According to an embodiment of the present disclosure, there is provided an integrated circuit, including: a first planar tier including: a first memory cell; and a second memory cell, the first memory cell including: a field-effect transistor, and a capacitor, the capacitor including: a first conductive layer, forming a first electrode of the capacitor, the first conductive layer being a tube having an axis parallel to a first direction; an insulating layer, on an inner surface and an outer surface of the first conductive layer; and a second conductive layer, on an inner surface and an outer surface of the insulating layer, the second conductive layer forming a second electrode of the capacitor, the first conductive layer having a maximum dimension, along a transverse direction, less than a channel width of the field-effect transistor, the transverse direction being perpendicular to an axis of the tube. For example, as may be seen from FIGS. 2C and 2D (which, as mentioned above, are drawn to scale), in some embodiments the dimension of the first conductive layer 175 in the Y direction may be less than the width of the channel 225 of the transistor 160.

In some embodiments, a center-to-center separation between the second memory cell and the first memory cell, along a second direction, is less than 130 nm, the second direction being parallel to the first planar tier and perpendicular to an axis of the tube. For example, the pitch of the Y-rows of transistors 160 and capacitors 165 may be less than 130 nm (e.g., the pitch may be between 70 nm and 130 nm, e.g., 115 nm).

As used herein, “a portion of” something means “at least some of” the thing, and as such may mean less than all of, or all of, the thing. As such, “a portion of” a thing includes the entire thing as a special case, i.e., the entire thing is an example of a portion of the thing. As used herein, when a second quantity is “within Y” of a first quantity X, it means that the second quantity is at least X-Y and the second quantity is at most X+Y. As used herein, when a second number is “within Y%” of a first number, it means that the second number is at least (1−Y/100) times the first number and the second number is at most (1+Y/100) times the first number. As used herein, the term “or” should be interpreted as “and/or”, such that, for example, “A or B” means any one of “A” or “B” or “A and B”.

The background provided in the Background section of the present disclosure section is included only to set context, and the content of this section is not admitted to be prior art. Any of the components or any combination of the components described (e.g., in any system diagrams included herein) may be used to perform one or more of the operations of any flow chart included herein. Further, (i) the operations are example operations, and may involve various additional steps not explicitly covered, and (ii) the temporal order of the operations may be varied.

As used herein, when a method (e.g., an adjustment) or a first quantity (e.g., a first variable) is referred to as being “based on” a second quantity (e.g., a second variable) it means that the second quantity is an input to the method or influences the first quantity, e.g., the second quantity may be an input (e.g., the only input, or one of several inputs) to a function that calculates the first quantity, or the first quantity may be equal to the second quantity, or the first quantity may be the same as (e.g., stored at the same location or locations in memory as) the second quantity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed herein could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that such spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the terms “substantially,” “about,” and similar terms are used as terms of approximation and not as terms of degree, and are intended to account for the inherent deviations in measured or calculated values that would be recognized by those of ordinary skill in the art.

As used herein, the term “major component” refers to a component that is present in a composition, polymer, or product in an amount greater than an amount of any other single component in the composition or product. In contrast, the term “primary component” refers to a component that makes up at least 50% by weight or more of the composition, polymer, or product. As used herein, the term “major portion”, when applied to a plurality of items, means at least half of the items. As used herein, any structure or layer that is described as being “made of” or “composed of” a substance should be understood (i) in some embodiments, to contain that substance as the primary component or (ii) in some embodiments, to contain that substance as the major component.

It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the present disclosure”. Also, the term “exemplary” is intended to refer to an example or illustration. As used herein, the terms “use,” “using,” and “used” may be considered synonymous with the terms “utilize,” “utilizing,” and “utilized,” respectively.

It will be understood that when an element or layer is referred to as being “on”, “connected to”, “coupled to”, or “adjacent to” another element or layer, it may be directly on, connected to, coupled to, or adjacent to the other element or layer, or one or more intervening elements or layers may be present. In contrast, when an element or layer is referred to as being “directly on”, “directly connected to”, “directly coupled to”, or “immediately adjacent to” another element or layer, there are no intervening elements or layers present.

Any numerical range recited herein is intended to include all sub-ranges of the same numerical precision subsumed within the recited range. For example, a range of “1.0 to 10.0” or “between 1.0 and 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Similarly, a range described as “within 35% of 10” is intended to include all subranges between (and including) the recited minimum value of 6.5 (i.e., (1−35/100) times 10) and the recited maximum value of 13.5 (i.e., (1±35/100) times 10), that is, having a minimum value equal to or greater than 6.5 and a maximum value equal to or less than 13.5, such as, for example, 7.4 to 10.6. Any maximum numerical limitation recited herein is intended to include all lower numerical limitations subsumed therein and any minimum numerical limitation recited in this specification is intended to include all higher numerical limitations subsumed therein.

It will be understood that when an element is referred to as being “directly connected” or “directly coupled” to another element, there are no intervening elements present. As used herein, “generally connected” means connected by an electrical path that may contain arbitrary intervening elements, including intervening elements the presence of which qualitatively changes the behavior of the circuit. As used herein, “connected” means (i) “directly connected” or (ii) connected with intervening elements, the intervening elements being ones (e.g., low-value resistors or inductors, or short sections of transmission line) that do not qualitatively affect the behavior of the circuit.

Although exemplary embodiments of a memory cell with a cylindrical capacitor have been specifically described and illustrated herein, many modifications and variations will be apparent to those skilled in the art. Accordingly, it is to be understood that a memory cell with a cylindrical capacitor constructed according to principles of this disclosure may be embodied other than as specifically described herein. The invention is also defined in the following claims, and equivalents thereof.

What is claimed is:

1. A system, comprising:
a field-effect transistor; and
a capacitor, the capacitor comprising:
a first conductive layer, forming a first electrode of the capacitor, the first conductive layer being a tube having an axis parallel to a first direction;
an insulating layer, on an inner surface and an outer surface of the first conductive layer; and
a second conductive layer, on an inner surface and an outer surface of the insulating layer, the second conductive layer forming a second electrode of the capacitor,
the insulating layer having a maximum dimension, along a transverse direction, less than a channel width of the field-effect transistor, the transverse direction being perpendicular to an axis of the tube.

2. The system of claim 1, comprising a first memory cell comprising the field-effect transistor and the capacitor.

3. The system of claim 2, comprising an integrated circuit comprising the first memory cell and a second memory cell, in a first planar tier of the integrated circuit.

4. The system of claim 3, wherein:
a center-to-center separation between the second memory cell and the first memory cell, along a second direction, is less than 130 nm; and
the second direction is parallel to the first planar tier and perpendicular to the axis of the tube.

5. The system of claim 4, wherein a capacitance of the capacitor is greater than 4 femtofarads.

6. The system of claim 5, wherein the capacitor has a maximum dimension less than 90 nm along the transverse direction.

7. The system of claim 4, wherein the capacitor has a maximum dimension less than 90 nm along the transverse direction.

8. The system of claim 3, wherein:
the integrated circuit comprises four planar tiers including the first planar tier, and
a mean pitch of the four planar tiers is less than 90 nm.

9. The system of claim 8, wherein a capacitance of the capacitor is greater than 4 femtofarads.

10. A system, comprising:
a field-effect transistor having a channel;
a capacitor; and
a contact connecting the channel to a first electrode of the capacitor,
the capacitor comprising:
a first conductive layer, forming the first electrode of the capacitor, the first conductive layer being a tube having an axis parallel to a first direction;
an insulating layer, on an inner surface and an outer surface of the first conductive layer; and
a second conductive layer, on an inner surface and an outer surface of the insulating layer, the second conductive layer forming a second electrode of the capacitor,
a first end of the contact being wider than a second end of the contact,
the first end of the contact being nearest the field-effect transistor, and
the second end of the contact being nearest the capacitor.

11. The system of claim 10, comprising a first memory cell comprising the field-effect transistor and the capacitor.

12. The system of claim 11, comprising an integrated circuit comprising the first memory cell and a second memory cell, in a first planar tier of the integrated circuit.

13. The system of claim 12, wherein:
a center-to-center separation between the second memory cell and the first memory cell, along a second direction, is less than 130 nm; and
the second direction is parallel to the first planar tier and perpendicular to the axis of the tube.

14. The system of claim 13, wherein a capacitance of the capacitor is greater than 4 femtofarads.

15. The system of claim 14, wherein the capacitor has a maximum dimension less than 90 nm along a transverse direction, the transverse direction being perpendicular to an axis of the tube.

16. The system of claim 13, wherein the capacitor has a maximum dimension less than 90 nm along a transverse direction, the transverse direction being perpendicular to an axis of the tube.

17. The system of claim 12, wherein:
the integrated circuit comprises four planar tiers including the first planar tier, and
a mean pitch of the four planar tiers is less than 90 nm.

18. The system of claim 17, wherein a capacitance of the capacitor is greater than 4 femtofarads.

19. An integrated circuit, comprising:
a first planar tier comprising:
a first memory cell; and
a second memory cell,
the first memory cell comprising:
a field-effect transistor, and
a capacitor,
the capacitor comprising:
a first conductive layer, forming a first electrode of the capacitor, the first conductive layer being a tube having an axis parallel to a first direction;
an insulating layer, on an inner surface and an outer surface of the first conductive layer; and
a second conductive layer, on an inner surface and an outer surface of the insulating layer, the second conductive layer forming a second electrode of the capacitor,
the first conductive layer having a maximum dimension, along a transverse direction, less than a channel width of the field-effect transistor, the transverse direction being perpendicular to an axis of the tube.

20. The integrated circuit of claim 19, wherein a center-to-center separation between the second memory cell and the first memory cell, along a second direction, is less than 130 nm, the second direction being parallel to the first planar tier and perpendicular to an axis of the tube.
